(19) United States
(12) Patent Application Publication
(10) Pub. No.: US 2018/0171479 A1
(43) Pub. Date: Jun. 21, 2018

(54) MATERIALS AND COATINGS FOR A SHOWERHEAD IN A PROCESSING SYSTEM

(71) Applicant: APPLIED MATERIALS, INC., SANTA CLARA, CA (US)

(72) Inventors: Son NGUYEN, San Jose, CA (US); Donald OLGADO, Palo Alto, CA (US); Yuriy MELNIK, San Jose, CA (US)

(21) Appl. No.: 15/823,382

(22) Filed: Nov. 27, 2017

Related U.S. Application Data
(63) Continuation of application No. 13/525,203, filed on Jun. 15, 2012, now abandoned.
(60) Provisional application No. 61/498,514, filed on Jun. 17, 2011.

(51) Int. Cl. C23C 16/455; C30B 25/14; C23C 16/44; C30B 29/40

(52) U.S. Cl. CPC C23C 16/45565; C30B 29/403; C23C 16/4404; C30B 25/14

(57) ABSTRACT

Apparatus and systems are disclosed for providing a protective material for a showerhead of a processing system. In an embodiment, a processing system includes a processing chamber for processing substrates and a showerhead having a diffuser plate for distributing processing gases to the processing chamber. The diffuser plate may include a protective material to protect the showerhead from processing gases. The diffuser plate may be formed with tungsten or tungsten coated with a tantalum alloy and tantalum.

### CROSS-REFERENCE TO RELATED APPLICATIONS

This application is a continuation of U.S. patent application Ser. No. 13/525,203, filed on Jun. 15, 2012, which claims benefit of U.S. Provisional Application No. 61/498,514, filed Jun. 17, 2011, the entire contents of which are hereby incorporated by reference herein.

### FIELD

Embodiments of this invention relate to materials and coatings for a showerhead in a processing system.

### BACKGROUND

Group-III nitride semiconductors are finding greater importance in the development and fabrication of short wavelength light emitting diodes (LEDs), laser diodes (LDs), and electronic devices including high power, high frequency, and high temperature transistors and integrated circuits. One method that has been used to deposit Group-III nitrides is hydride vapor phase epitaxy (HVPE). In HVPE, a hydride gas reacts with the Group-III metal which then reacts with a nitrogen precursor to form the Group-III metal nitride. The processing gases for HVPE may be corrosive to the gas delivery particularly at elevated temperatures.

### SUMMARY

Apparatus and systems are disclosed for providing a protective material for a gas-delivery system of a processing system. In an embodiment, a processing system includes a processing chamber for processing substrates and a gas-delivery system for delivering processing gases to the processing chamber. The gas-delivery system includes a protective material to protect the gas-delivery system from processing gases including at least one processing gas heated to an elevated temperature. The protective material may include a tungsten plate or a tungsten plate coated with a tantalum alloy and tantalum

In another embodiment, a processing system includes a processing chamber for processing substrates and a showerhead having a diffuser plate for distributing processing gases to the processing chamber. The diffuser plate may include a protective material to protect the showerhead from processing gases. The diffuser plate may be formed with tungsten or tungsten coated with a tantalum alloy and tantalum. The protective material may be used to protect other components in the processing chamber. The showerhead and other components exposed to the processing gases are resistant to the processing gases at temperatures of 550 degrees C. and higher.

### BRIEF DESCRIPTION OF THE DRAWINGS

Embodiments of the present invention are illustrated by way of example, and not by way of limitation, in the figures of the accompanying drawings, in which:

FIG. 1 illustrates a processing system that includes a gas-delivery system having a protective material in accordance with one embodiment.

FIG. 2 illustrates a processing chamber 250 with one or more showerheads in accordance with one embodiment.

FIG. 3 illustrates a processing chamber 300 with a showerhead 310 in accordance with another embodiment.

FIG. 4 is a schematic view of an HVPE apparatus 100 according to one embodiment.

FIG. 5 illustrates a MOCVD apparatus in accordance with an embodiment.

FIG. 6 illustrates a cluster tool in accordance with one embodiment.

FIG. 7 illustrates a cross-sectional view of a device in accordance with one embodiment.

FIG. 8 illustrates a showerhead assembly in accordance with one embodiment.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

Apparatus and systems are disclosed for providing protective materials and coatings for a showerhead of a processing system. In an embodiment, a processing system includes a processing chamber for processing substrates and a showerhead having a diffuser plate for distributing processing gases to the processing chamber. The diffuser plate may include a protective material to protect the showerhead from processing gases. The diffuser plate may be formed with tungsten or tungsten coated with a tantalum alloy and tantalum. The protective material may be used to form other components in the processing chamber. The showerhead and other components exposed to the processing gases are resistant to the processing gases at temperatures of 550 degrees C. and higher.

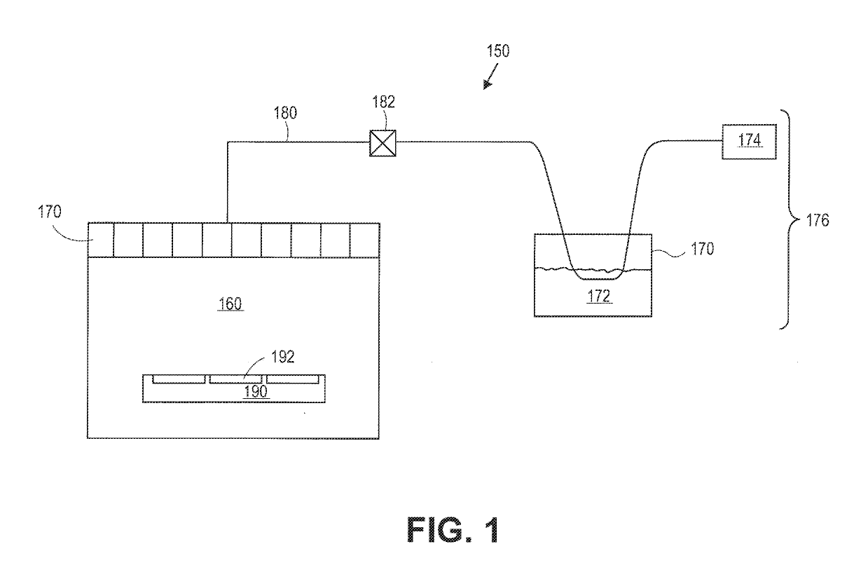

FIG. 1 illustrates a processing system that includes a gas-delivery system gas-delivery system includes a protective coating in accordance with another embodiment. The processing system 150 includes a chamber 160 and showerhead 170 for distributing processing gases in the chamber, which also includes a susceptor 190 for holding substrates 192. In order to provide uniform distribution of processing gases into a semiconductor processing chamber (such as an etch chamber or a deposition chamber), a “showerhead” type gas distribution assembly has been adopted as a standard in the semiconductor manufacturing industry. The gas-delivery system 176 includes a source 172 in an ampoule 172, a carrier source 174, a gas line 180, and one or more valves 182. The gas line 180 may include one or more O-rings for coupling components of the gas line 180. The ampoule may include a typical bubbler structure that may be used in providing the precursor source 172 to the processing chamber 160 from a liquid or solid precursor source. The illustration provided in FIG. 1 is for a single precursor source 172, but it will be understood that such a structure may be replicated one or more times for additional sources so that the gas or vapor delivery system 176 shown in FIG. 1 has access to sufficient sources to implement deposition processes for different materials.

A suitable carrier gas is applied to the precursor 172 from a carrier-gas source (e.g., 174) to generate a saturated mixture of precursor vapor dissolved in the carrier gas. The carrier gas is commonly molecular hydrogen H2 although a variety of other carrier gases may be used in different embodiments. In the case of nitride deposition, molecular nitrogen N2 or a mixture of H2 and N2 are sometimes used as carrier gases. In various other applications, an inert gas like He, Ne, Ar, or Kr may be used as the carrier gas. The mixture is flowed to the processing chamber 160 where CVD processes may be carried out. The absolute flow of precursor vapor may be metered by controlling the flow of carrier gas, the total pressure in the bubbler, and the temperature of the precursor (which determines the vapor pressure).

As precursor is consumed in performing CVD processes in the processing chamber, one or more processing gases are delivered to the processing chamber 160 via the gas-delivery system 176, which includes the processing gas line 180.

In one embodiment, to deliver a metallic chloride precursor such as a gallium chloride precursor (e.g., GaCl, GaCl3) to the chamber 160 a precursor source 172 (e.g., GaCl, GaCl3) is kept in an ampoule 170. The gallium trichloride (GaCl3) in a solid form is heated to 70-100 degrees C. until the GaCl3 is a liquid. Then, the carrier gas is bubbled through the GaCl3 liquid to deliver GaCl3 to the chamber 160. The carrier gas may have a flow rate of 2-9 slpm. The ampoule 170 and components of the gas-delivery system 176 may be formed from a protective material (e.g., tungsten plate, tungsten plate coated with a tantalum alloy and a tantalum outer layer) or be coated with a protective coating for protection from the highly corrosive GaCl3, which may be at an elevated temperature (e.g., 70-200 degrees C., 120-200 degrees C.) in the gas-delivery system 176. The valves, gas lines, fittings, etc. of the gas-delivery system may need to be heated to this temperature range in order to avoid condensing the GaCl3. The protective coating may be tantalum, TANTALINE™, a nickel based coating (e.g., HASTELLOY™), refractory metals, refractory alloys, W, TaN, WN, and combinations thereof. TANTALINE products include a core substrate (e.g., stainless steel, metals and alloys based on Iron, Cobalt, Chromium, Copper, CoCr alloys, metal oxide ceramics) which is treated to create an inert and corrosion resistant tantalum surface. Through the TANTALINE process, tantalum atoms are grown into the substrate (plate) creating a nanoscale inseparable surface alloy. The processing chamber 160 and gas line 180 may be held at a sub atmospheric level (e.g., 10-8 up to 640 torr). A showerhead 170 with a protective coating may be heated to a temperature (e.g., 500-800 degrees C., 550-600 degrees C.) and does not corrode while exposed to various processing gases including GaCl3, GaCl, Cl2, HCL.

A tantalum coating may be formed on a substrate or plate (e.g., stainless steel) using a CVD process flow. The tantalum coating can be as thick as possible in order to form the protective coating. The tantalum etches the stainless steel substrate or plate during the CVD process so that after the deposition a coated component has substantially the same internal volume.

In one embodiment, the showerhead 170 and other components exposed to the processing gases include a protective material (e.g., tungsten plate, tungsten plate coated with a tantalum alloy and a tantalum outer layer). In another embodiment, the showerhead 170 and other components include a protective coating (e.g., tantalum, TANTALINE, refractory metal) as discussed herein and will be resistant to the processing gases at a temperature of 550 degrees C. and below.

In another embodiment, the showerhead and other components exposed to the processing gases particularly at elevated temperatures are resistant to the processing gases at higher temperatures of 550 degrees C. and higher (e.g, 550-800 degrees C., 550-600 degrees C.). The high temperature showerhead includes tungsten (W) or tungsten coated with a tantalum alloy and a tantalum outer layer (e.g., tungsten TANTALINE (WL)) as substrate (plate) materials and optionally a protective coating that includes at least one of: Al2O3, WC, BN, TaN, Si3N4, B4C. These coatings can be applied on W or WL plate using a CVD deposition method to prevent any porosities and microcrackings in the protective coating. These coatings have very similar thermal expansion coefficients (TCE) with W and WL allowing the protective coating to adhere to the substrate well at typically processing temperatures (e.g., 500-800 degrees C.). W has a TCE of approximately 4.5 and the other materials have TCEs in the range of 3-8. Tungsten may be the least attacked or most resistant material of the materials exposed to the processing gases. The showerhead and other components coated with the protective coating are inert to various processing gases including GaCl3, GaCl, Cl2, HCL.

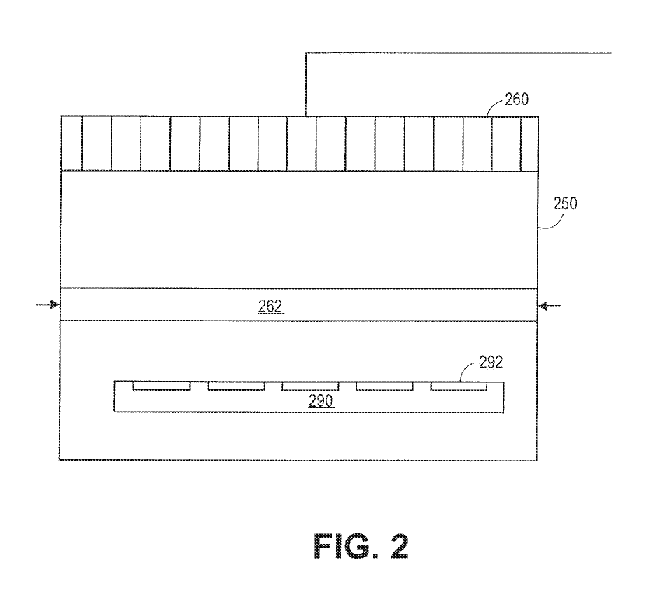

FIG. 2 illustrates a processing chamber 250 with one or more showerheads in accordance with one embodiment. The showerhead 260 may be heated to 550-600 degrees C. and be inert to various processing gases including GaCl3, GaCl, Cl2, HCL, NH3. The showerhead 260 may distribute processing gases (e.g., NH3) into the chamber 250. A lower showerhead 262 or ring may distribute processing gases (e.g., GaCl, GaCl3) into the chamber 250. The chamber includes a suspector 290 for supporting substrates 292. In one embodiment, the showerheads and other components exposed to the processing gases in the chamber include a protective material (e.g., tungsten plate, tungsten plate coated with a tantalum alloy and a tantalum outer layer). In another embodiment, the showerhead 170 and other components include a protective coating. The high temperature protective coating may be coated on tungsten (W) or tungsten TANTALINE (WL) as substrate (plate) materials (e.g., for the showerheads) and the protective coating includes at least one of: Al2O3, WC, BN, TaN, Si3N4, B4C.

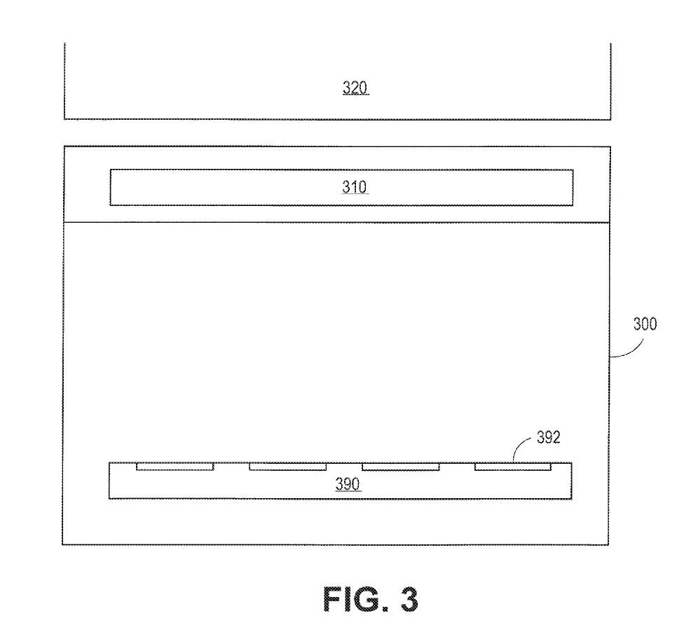

FIG. 3 illustrates a processing chamber 300 with a showerhead 310 in accordance with another embodiment. The showerhead 310 may include multiple zones (e.g., 3 zones), multiple plenums (e.g., 2 plenums), and have convection air cooling (e.g., N2). The showerhead 310 may include a heat sink 320 or be coupled to a heat sink to cool the showerhead and keep the temperature of the showerhead at lower temperatures (e.g., 550 degrees or lower) during HVPE processing. The showerhead may be heated to 550 degrees C. or less and be inert to various processing gases including GaCl3, GaCl, Cl2, HCL.

The chamber includes a suspector 390 for supporting substrates 392. In one embodiment, the showerhead and other components exposed to the processing gases in the chamber include a protective material (e.g., tungsten plate, tungsten plate coated with a tantalum alloy and a tantalum outer layer). In another embodiment, the showerhead 170 and other components include a protective coating. The protective coating may be tantalum, TANTALINE, a nickel based coating (e.g., HASTELLOY), refractory metals, refractory alloys, W, TaN, WN, etc.), and combinations thereof. Alternatively, the protective coating may be coated on tungsten (W) or tungsten TANTALINE (WL) as substrate materials (e.g., for the showerhead) and the protective coating includes at least one of: Al2O3, WC, BN, TaN, Si3N4, B4C.

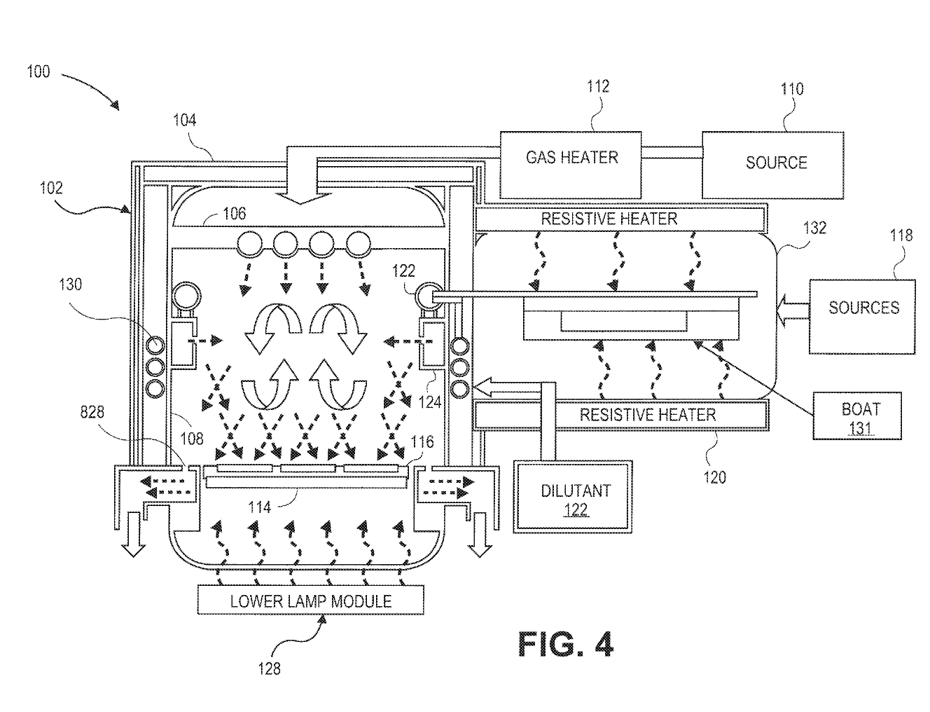

FIG. 4 is a schematic view of an HVPE apparatus 100 according to one embodiment. The apparatus 100 includes a chamber 102 enclosed by a lid 104. Processing gas from a first gas source 110 is delivered to the chamber 102 through a gas distribution showerhead 106. In one embodiment, the gas source 110 may include a nitrogen containing compound. In another embodiment, the gas source 110 may include ammonia. In one embodiment, an inert gas such as helium or diatomic nitrogen may be introduced as well either through the gas distribution showerhead 106 or through the walls 108 of the chamber 102. An energy source 112 may be disposed between the gas source 110 and the gas distribution showerhead 106. In one embodiment, the energy source 112 may include a heater. The energy source 112 may break up the gas from the gas source 110, such as ammonia, so that the nitrogen from the nitrogen containing gas is more reactive.

To react with the gas from the first source 110, precursor material may be delivered from one or more second sources 118. The one or more second sources 118 may include precursors such as gallium and aluminum. It is to be understood that while reference will be made to two precursors, more or less precursors may be delivered as discussed above. In one embodiment, the precursor includes gallium present in the one or more second sources 118 in liquid form. In one embodiment, the precursor present in the one or more second sources 118 may be in liquid form. In another embodiment, the precursor may be present in the one or more second sources in solid form or solid powder form (e.g., GaCl3). In another embodiment, the precursor includes aluminum present in the precursor source 118 in solid form. In one embodiment, the aluminum precursor may be in solid, powder form. The precursor may be delivered to the chamber 102 by flowing a reactive gas over and/or through the precursor in the precursor source 118. Alternatively, the precursor may be delivered to the chamber 102 by bubbling a carrier gas through the precursor source. In one embodiment, the reactive gas may include a halogen gas. In one embodiment, the reactive gas may include a chlorine containing gas such as diatomic chlorine. The chlorine containing gas may react with the precursor source such as gallium or aluminum to form a chloride. In one embodiment, the one or more second sources 118 may include eutectic materials and their alloys. In another embodiment, the HVPE apparatus 100 may be arranged to handle doped sources as well as at least one intrinsic source to control the dopant concentration.

In order to increase the effectiveness of the chlorine containing gas to react with the precursor, the chlorine containing gas may snake through the boat area in the chamber 132 and be heated with the resistive heater 120. By increasing the residence time that the chlorine containing gas is snaked through the chamber 132, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 120 within the second chamber 132 in a boat 131. For example, in one embodiment, the gallium precursor may be heated to a temperature of between about 750 degrees Celsius to about 850 degrees Celsius. The chloride reaction product may then be delivered to the chamber 102. The reactive chloride product first enters a tube 122 where it evenly distributes within the tube 122. The tube 122 is connected to another tube 124. The chloride reaction product enters the second tube 124 after it has been evenly distributed within the first tube 122. The chloride reaction product then enters into the chamber 102 where it mixes with the nitrogen containing gas to form a nitride layer on the substrate 116 that is disposed on a susceptor 114. In one embodiment, the susceptor 114 may include silicon carbide. The nitride layer may include gallium nitride or aluminum nitride for example. The other reaction product, such as nitrogen and chlorine, is exhausted through an exhaust 126.

The chamber 102 may have a thermal gradient that can lead to a buoyancy effect. For example, the nitrogen based gas is introduced through the gas distribution showerhead 106 at a temperature between about 450 degrees Celsius and about 600 degrees Celsius. The chamber walls 108 may have a temperature of about 600 degrees Celsius to about 700 degrees Celsius. The susceptor 114 may have a temperature of about 1050 to about 1150 degrees Celsius. Thus, the temperature difference within the chamber 102 may permit the gas to rise within the chamber 102 as it is heated and then fall as it cools. The rising and falling of the gas may cause the nitrogen gas and the chloride gas to mix. Additionally, the buoyancy effect will reduce the amount of gallium nitride or aluminum nitride that deposits on the walls 108 because of the mixing.

The heating of the processing chamber 102 is accomplished by heating the susceptor 114 with a lamp module 128 that is disposed below the susceptor 114. During deposition, the lamp module 128 is the main source of heat for the processing chamber 102. While shown and described as a lamp module 128, it is to be understood that other heating sources may be used. Additional heating of the processing chamber 102 may be accomplished by use of a heater 130 embedded within the walls 108 of the chamber 102. The heater 130 embedded in the walls 108 may provide little if any heat during the deposition process.

In general, a deposition process will proceed as follows. A substrate 116 may initially be inserted into the processing chamber 102 and disposed on the susceptor 114. In one embodiment, the substrate 116 may include sapphire. The lamp module 128 may be turned on to heat the substrate 16 and correspondingly the chamber 102. Nitrogen containing reactive gas may be introduced from a first source 110 to the processing chamber. The nitrogen containing gas may pass through an energy source 112 such as a gas heater to bring the nitrogen containing gas into a more reactive state. The nitrogen containing gas then passes through the chamber lid 104 and the gas distribution showerhead 106. In one embodiment, the chamber lid 104 may be water cooled.

A precursor may also be delivered to the chamber 102. A chlorine containing gas may pass through and/or over the precursor in a precursor source 118. The chlorine containing gas then reacts with the precursor to form a chloride. The chloride is heated with a resistive heater 120 in the source chamber 132 and then delivered into an upper tube 122 where it evenly distributes within the tube 122. The chloride gas then flows down into the other tube 124 before it is introduced into the interior of the chamber 102. It is to be understood that while chlorine containing gas has been discussed, the invention is not to be limited to chlorine containing gas. Rather, other compounds may be used in the HVPE process. A dilutent gas may also be introduced into the processing chamber. The chamber walls 118 may have a minimal amount of heat generated from the heater 130 embedded within the walls 118. The majority of the heat within the chamber 120 is generated by the lamp module 128 below the susceptor 114.

Due to the thermal gradient within the chamber 102, the chloride gas and the nitrogen containing gas rise and fall within the processing chamber 102 and thus intermix to form a nitride compound that is deposited on the substrate 116. In addition to depositing on the substrate 116, the nitride layer may deposit on other exposed areas of the chamber 102 as well. The gaseous reaction product of the chloride compound and the nitrogen containing gas may include chlorine and nitrogen which may be evacuated out of the chamber thought the vacuum exhaust 126.

While the nitrogen containing gas is discussed as being introduced through the gas distribution showerhead 106 and the precursor delivered in the area corresponding to the middle of the chamber 102, it is to be understood that the gas introduction locations may be reversed. However, if the precursor is introduced through the showerhead 106, the showerhead 106 may be heated to increase the reactiveness of the chloride reaction product.

Because the chloride reaction product and the ammonia are delivered at different temperatures, delivering the ammonia and the chloride reaction product through a common feed may be problematic. For example, if a quartz showerhead were used to feed both the ammonia and the chloride reaction product, the quartz showerhead may crack due to the different temperatures of the ammonia and the chloride reaction product.

Additionally, the deposition process may involve depositing a thin aluminum nitride layer as a seed layer over the sapphire substrate followed by a gallium nitride layer. Both the gallium nitride and the aluminum nitride may be deposited within the same processing chamber. Thereafter, the sapphire substrate may be removed and placed into an MOCVD processing chamber were another layer may be deposited. In some embodiments, the aluminum nitride layer may be eliminated. Where both an aluminum nitride layer and a gallium nitride layer are deposited within the same chamber, a diatomic nitrogen back flow may be used to prevent any of the other precursor from reacting with chlorine and forming a chloride reaction product. The diatomic nitrogen may be flowed into the chamber of the precursor not being reacted while the chlorine may be flowed into contact with the other precursor. Thus, only one precursor is reacted at a time.

In one embodiment, to deliver a metallic chloride precursor such as a gallium chloride precursor (e.g., GaCl, GaCl3) to the chamber 102 a precursor source 110 or 118 (e.g., GaCl, GaCl3) is kept in an ampoule. The gallium trichloride (GaCl3) in a solid form is heated to 70-100 degrees C. until the GaCl3 is a liquid. Then, a carrier gas is bubbled through the GaCl3 liquid to deliver GaCl3 to the chamber 102. The carrier gas may have a flow rate of 2-9 slpm. The ampoule and components of the gas-delivery system may include a protective material (e.g., tungsten plate, tungsten plate coated with a tantalum alloy and a tantalum outer layer). In another embodiment, the ampoule and components of the gas-delivery system are coated with a protective coating for protection from the highly corrosive GaCl3, which may be at a temperature (e.g., 70-200 degrees C., 120-200 degrees C.) in the gas-delivery system, which includes valves, gas lines, fittings, etc. The gas-delivery system needs to be heated to this temperature range in order to avoid condensing the GaCl3. The protective coating may be tantalum, TANTALINE, a nickel based coating (e.g., HASTELLOY), refractory metals, refractory alloys, W, TaN, WN, etc.), and combinations thereof. A showerhead 106 with a protective coating may be heated to a temperature (e.g., 500-800 degrees C., 550-600 degrees C.) and not corrode while exposed to various processing gases including GaCl3, GaCl, Cl2, HCL.

Alternatively, the protective coating may be coated on tungsten (W) or tungsten TANTALINE (WL) as substrate (plate) materials (e.g., for the showerhead 106) and the protective coating includes at least one of: Al2O3, WC, BN, TaN, Si3N4, B4C. Other components exposed to the processing gases may be coated with the protective coating.

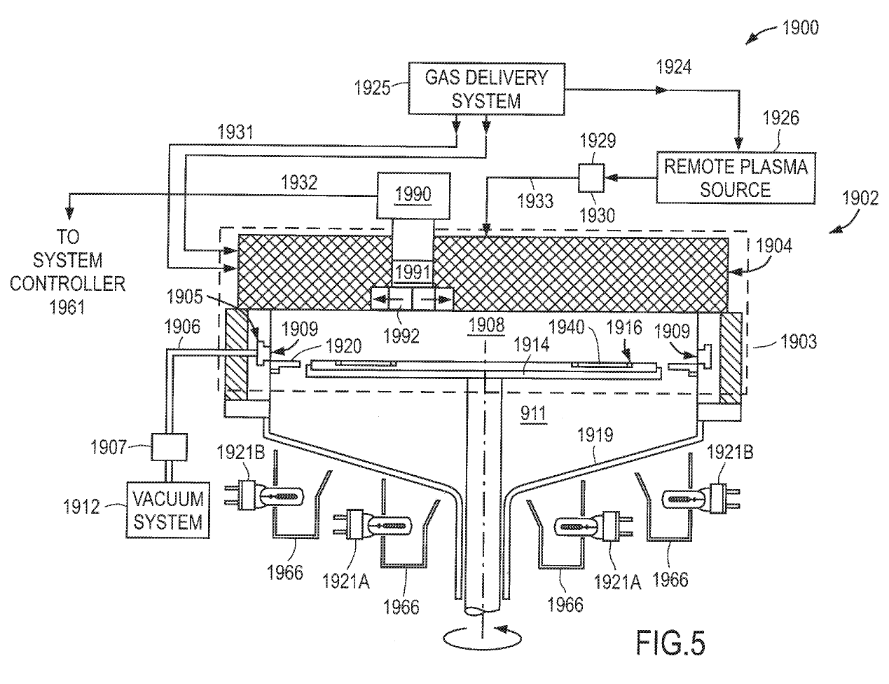

In FIG. 5 an MOCVD apparatus configured with in-situ temperature measurement hardware including the pyrometer 1990, window 1991 and shutter 1992 is illustrated. The MOCVD apparatus 1900 shown in FIG. 5 includes a chamber 1902, a gas delivery system 1925, a remote plasma source 1926, a vacuum system 1912, and a system controller 1961. The chamber 1902 includes a chamber body 1903 that encloses a processing volume 1908. A showerhead assembly 1904 is disposed at one end of the processing volume 1908, and a substrate carrier 1914 is disposed at the other end of the processing volume 1908. A lower dome 1919 is disposed at one end of a lower volume 1911, and the substrate carrier 1914 is disposed at the other end of the lower volume 1911. The substrate carrier 1914 is shown in process position, but may be moved to a lower position where, for example, the substrates 1940 may be loaded or unloaded. An exhaust ring 1920 may be disposed around the periphery of the substrate carrier 1914 to help prevent deposition from occurring in the lower volume 1911 and also help direct exhaust gases from the chamber 1902 to exhaust ports 1909.

The lower dome 1919 may be made of transparent material, such as high-purity quartz, to allow light to pass through for radiant heating of the substrates 1940. The radiant heating may be provided by a plurality of inner lamps 1921A and outer lamps 1921B disposed below the lower dome 1919. Reflectors 1966 may be used to help control chamber 1902 exposure to the radiant energy provided by inner and outer lamps 1921A, 1921B. Additional rings of lamps may also be used for finer temperature control of the substrates 1940.

Returning to FIG. 5, the substrate carrier 1914 may include one or more recesses 1916 within which one or more substrates 1940 may be disposed during processing. The substrate carrier 1914 may carry one or more substrates 1940. In one embodiment, the substrate carrier 1914 carries eight substrates 1940. It is to be understood that more or less substrates 1940 may be carried on the substrate carrier 1914. Typical substrates 1940 may include sapphire, silicon carbide (SiC), silicon, or gallium nitride (GaN). It is to be understood that other types of substrates 1940, such as glass substrates 1940, may be processed. Substrate 1940 size may range from 50 mm-300 mm in diameter or larger. The substrate carrier 1914 size may range from 200 mm-750 mm. The substrate carrier 1914 may be formed from a variety of materials, including SiC or SiC-coated graphite. It is to be understood that substrates 1940 of other sizes may be processed within the chamber 1902 and according to the processes described herein. The showerhead assembly 1904, as described herein, may allow for more uniform deposition across a greater number of substrates 1940 and/or larger substrates 1940 than in traditional MOCVD chambers, thereby increasing throughput and reducing processing cost per substrate 1940.

The substrate carrier 1914 may rotate about an axis during processing. In one embodiment, the substrate carrier 1914 may be rotated at about 2 RPM to about 100 RPM. In another embodiment, the substrate carrier 1914 may be rotated at about 30 RPM. Rotating the substrate carrier 1914 aids in providing uniform heating of the substrates 1940 and uniform exposure of the processing gases to each substrate 1940.

The plurality of inner and outer lamps 1921A, 1921B may be arranged in concentric circles or zones (not shown), and each lamp zone may be separately powered. In one embodiment, one or more temperature sensors, such as pyrometers (not shown), may be disposed within the showerhead assembly 1904 to measure substrate 1940 and substrate carrier 1914 temperatures, and the temperature data may be sent to a controller (not shown) which can adjust power to separate lamp zones to maintain a predetermined temperature profile across the substrate carrier 1914. In another embodiment, the power to separate lamp zones may be adjusted to compensate for precursor flow or precursor concentration non-uniformity. For example, if the precursor concentration is lower in a substrate carrier 1914 region near an outer lamp zone, the power to the outer lamp zone may be adjusted to help compensate for the precursor depletion in this region.

The inner and outer lamps 1921A, 1921B may heat the substrates 1940 to a temperature of about 400 degrees Celsius to about 1200 degrees Celsius. It is to be understood that embodiments of the invention are not restricted to the use of arrays of inner and outer lamps 1921A, 1921B. Any suitable heating source may be utilized to ensure that the proper temperature is adequately applied to the chamber 1902 and substrates 1940 therein. For example, in another embodiment, the heating source may include resistive heating elements (not shown) which are in thermal contact with the substrate carrier 1914.

A gas delivery system 1925 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 1902. Different gases, such as precursor gases, carrier gases, purge gases, cleaning/etching gases or others may be supplied from the gas delivery system 1925 to separate supply lines 1931, 1932, and 1933 to the showerhead assembly 1904. The supply lines 1931, 1932, and 1933 may include shut-off valves and mass flow controllers or other types of controllers to monitor and regulate or shut off the flow of gas in each line.

A conduit 1929 may receive cleaning/etching gases from a remote plasma source 1926. The remote plasma source 1926 may receive gases from the gas delivery system 1925 via supply line 1924, and a valve 1930 may be disposed between the showerhead assembly 1904 and remote plasma source 1926. The valve 1930 may be opened to allow a cleaning and/or etching gas or plasma to flow into the showerhead assembly 1904 via supply line 1933 which may be adapted to function as a conduit for a plasma. In another embodiment, MOCVD apparatus 1900 may not include remote plasma source 1926 and cleaning/etching gases may be delivered from gas delivery system 1925 for non-plasma cleaning and/or etching using alternate supply line configurations to shower head assembly 1904.

The remote plasma source 1926 may be a radio frequency or microwave plasma source adapted for chamber 1902 cleaning and/or substrate 1940 etching. Cleaning and/or etching gas may be supplied to the remote plasma source 1926 via supply line 1924 to produce plasma species which may be sent via conduit 1929 and supply line 1933 for dispersion through showerhead assembly 1904 into chamber 1902. Gases for a cleaning application may include fluorine, chlorine or other reactive elements.

In another embodiment, the gas delivery system 1925 and remote plasma source 1926 may be suitably adapted so that precursor gases may be supplied to the remote plasma source 1926 to produce plasma species which may be sent through showerhead assembly 1904 to deposit CVD layers, such as III-V films, for example, on substrates 1940.

A purge gas (e.g., nitrogen) may be delivered into the chamber 1902 from the showerhead assembly 1904 and/or from inlet ports or tubes (not shown) disposed below the substrate carrier 1914 and near the bottom of the chamber body 1903. The purge gas enters the lower volume 1911 of the chamber 1902 and flows upwards past the substrate carrier 1914 and exhaust ring 1920 and into multiple exhaust ports 1909 which are disposed around an annular exhaust channel 1905.

An exhaust conduit 1906 connects the annular exhaust channel 1905 to a vacuum system 1912 which includes a vacuum pump (not shown). The chamber 1902 pressure may be controlled using a valve system 1907 which controls the rate at which the exhaust gases are drawn from the annular exhaust channel 1905.

Different components of the gas-delivery system and chamber may need to be coated with a protective coating for protection from the corrosive processing gases. In one embodiment, the protective coating may be tantalum, TANTALINE, a nickel based coating (e.g., HASTELLOY), refractory metals, refractory alloys, W, TaN, WN, etc.), and combinations thereof. A showerhead assembly 1904 with a protective coating may be heated to a certain temperature and not corrode while exposed to various processing gases.

Alternatively, the protective coating may be coated on tungsten (W) or tungsten TANTALINE (WL) as substrate or plate materials (e.g., for the showerhead assembly 1904) and the protective coating includes at least one of: Al2O3, WC, BN, TaN, Si3N4, B4C. Other components exposed to the processing gases may be coated with the protective coating.

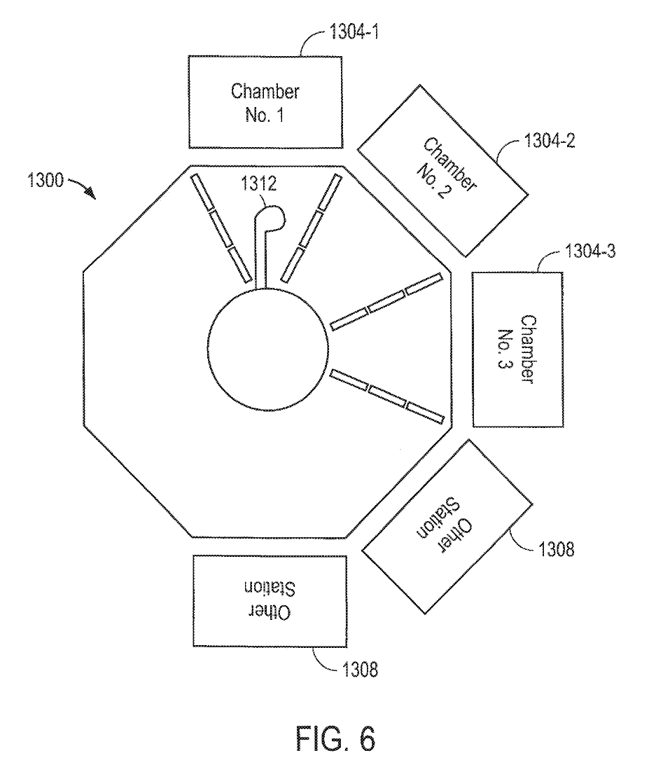

The HVPE systems and apparatuses described herein and the MOCVD apparatus 1900 may be used in a processing system which includes a cluster tool that is adapted to process substrates and analyze the results of the processes performed on the substrate. The physical structure of the cluster tool is illustrated schematically in FIG. 6. In this illustration, the cluster tool 1300 includes three processing chambers 1304-1, 1304-2, 1304-3, and two additional stations 1308, with robotics 1312 adapted to effect transfers of substrates between the chambers 1304 and stations 1308. The structure permits the transfers to be effected in a defined ambient environment, including under vacuum, in the presence of a selected gas, under defined temperature conditions, and the like. The cluster tool is a modular system including multiple chambers that perform various processing operations that are used to form an electronic device. The cluster tool may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif.

For a single chamber process, layers of differing composition are grown successively as different steps of a growth recipe executed within the single chamber. For a multiple chamber process, layers in a III-V or II-VI structure are grown in a sequence of separate chambers. For example, an undoped/nGaN layer may be grown in a first chamber, a MQW structure grown in a second chamber, and a pGaN layer grown in a third chamber.

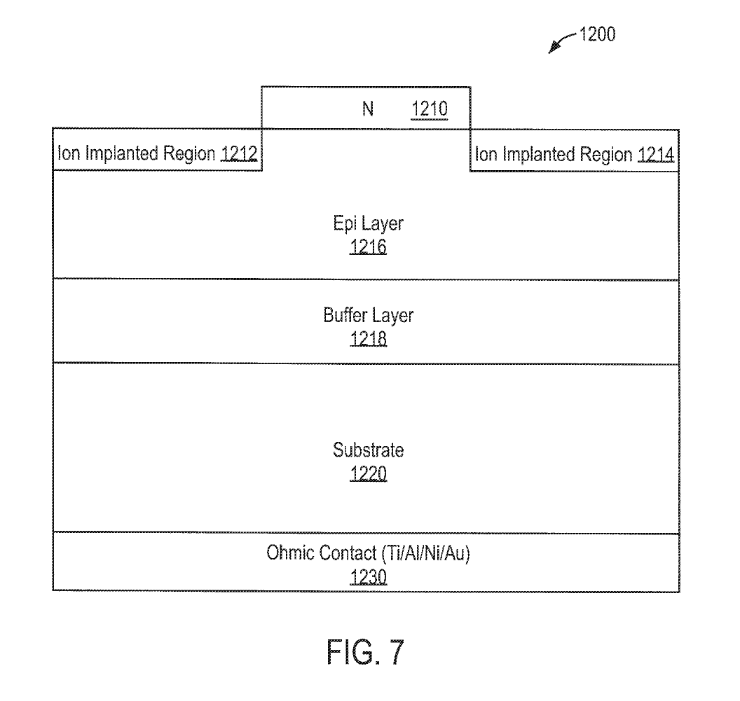

FIG. 7 illustrates a cross-sectional view of a power electronics device in accordance with one embodiment. The power electronic device 1200 may include an N type region 1210 (e.g., electrode), ion implanted regions 1212 and 1214, an epitaxial layer 1216 (e.g., N type GaN epi layer with a thickness of 4 microns), a buffer layer (e.g., N+ GaN buffer layer with a thickness of 2 microns), a substrate 1220 (e.g., N+ bulk GaN substrate, silicon substrate), and an ohmic contact (e.g., Ti/Al/Ni/Au). The device 1200 may include one or more layers of GaN disposed on a GaN substrate or a silicon substrate. The device (e.g., power IC, power diode, power thyristor, power MOSFET, IGBT, GaN HEMT transistor) may be used for switches or rectifiers in power electronics circuits and modules.

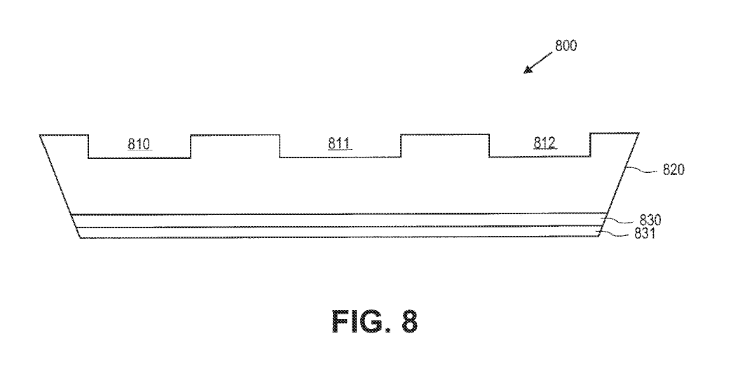

Processing gases may be introduced into a processing chamber through a showerhead assembly. FIG. 8 illustrates a showerhead assembly in accordance with one embodiment. The showerhead assembly 800 may include multiple plenums 810-812, a diffuser plate 820, and optionally one or more coating materials 830 and 831. The coating materials are shown coated on a lower surface of the plate 820. It may also be coated on other surfaces (e.g. side surfaces) of the plate 820. In one embodiment, the diffuser plate 820 may include tungsten. The optional coating material 830 may include a tantalum alloy and the optional coating material 831 may include a tantalum layer. Alternatively, the coating materials 830 and 831 are replaced with a protective coating that includes at least one of aluminum oxide (Al2O3), tungsten carbide (WC), boron nitride (BN), tantalum nitride (TaN), silicon nitride (Si3N4), and boron carbide (B4C). In another embodiment, the protective coating is applied to the coating material 831. The showerhead 820 may be coupled with at least one gas source by at least one conduit of a gas-delivery system. Gas from the at least one gas source may flow through the at least one conduit to one or more plenums 810-812 disposed behind the diffuser plate 820 of the showerhead 800. At least one valve may be disposed along the conduit(s) to control the amount of gas that flows from the gas source(s) to the plenums. Once the gas enters the plenums, the gas may then pass through openings (not shown) in the diffuser plate 820 and corresponding openings (not shown) in optional coating materials 830 and 831.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A processing system, comprising:
a processing chamber for processing substrates; and
a showerhead having a plate for distributing processing gases to the processing chamber, the plate including a protective material to protect the showerhead from processing gases, wherein the protective material includes tungsten.
